(19) United States
(12) Patent Application Publication
(10) Pub. No.: US 2021/0021100 A1
(43) Pub. Date: Jan. 21, 2021

(54) EXTERAL CAVITY LASER INCORPORATING A RESETABLE PHASE SHIFTER

(71) Applicant: Nokia Technologies Oy, Espoo (FI)

(72) Inventors: Argishti Melikyan, Marlboro, NJ (US); Po Dong, Morganville, NJ (US)

(21) Appl. No.: 16/513,904

(22) Filed: Jul. 17, 2019

(51) Int. Cl. H01S 5/14; G02B 6/293; H01S 3/1055; H01S 5/0625

(52) U.S. Cl. CPC H01S 5/141; H01S 5/06256; H01S 3/1055; G02B 6/29316

(57) ABSTRACT

An apparatus including an external cavity laser with an optical cavity, the optical cavity bounded by optical reflectors. The optical cavity can include an optical gain module capable of amplifying light, a tunable endless optical phase shifter and a wavelength-tunable optical filter. The apparatus can also include an electronic control module connected to enable adjustment of a phase shift accumulated by the light propagating through the tunable endless optical phase shifter and connected to enable adjustment of a passband wavelength of the wavelength tunable optical filter. Another apparatus as described above with no wavelength-tunable optical filter present.

### TECHNICAL FIELD

The invention relates, in general, to an apparatus including a wavelength-tunable external cavity laser.

### BACKGROUND

This section introduces aspects that may help facilitate a better understanding of the inventions. Accordingly, the statements of this section are to be read in this light and are not to be understood as admissions about what is prior art or what is not prior art.

Wavelength tunable external-cavity lasers are often constructed using mechanically moving parts e.g. diffraction gratings or mirrors moved using piezoelectric transducers. One problem with some such lasers is that their range of wavelength tunability, while maintaining about a same lasing optical power and same optical mode in the cavity, can be more limited than desired. Other disadvantages of such a laser may include the laser's relatively larger size, an inability to rapidly scan over a wavelength tuning range, and/or the high cost to fabricate such a laser.

### SUMMARY

One embodiment includes an apparatus, the apparatus including an external cavity laser with an optical cavity, the optical cavity bounded by optical reflectors. The optical cavity can include an optical gain module capable of amplifying light, a tunable endless optical phase shifter and a wavelength-tunable optical filter. The apparatus can also include an electronic control module connected to enable adjustment of a phase shift accumulated by the light propagating through the tunable endless optical phase shifter and connected to enable adjustment of a passband wavelength of the wavelength tunable optical filter.

In some embodiments, the electronic control module can be capable of adjusting the accumulated phase shift and the passband wavelength in parallel. In some such embodiments, the electronic control module can be capable of switching an optical path of the light propagating therethrough without changing the accumulated phase shift other than multiple of 2π. In some such embodiments, the wavelength-tunable optical filter can include at least one wavelength-tunable, loop resonator. In some such embodiments, the electronic control module can be capable capable of switching an optical path of light propagating therethrough without changing the accumulated phase shift other than a multiple of 2π. In some such embodiments, the electronic control module can be configured to control an operational state of the optical gain module.

In some embodiments, the electronic control module can cause a phase shift accumulated by the light propagating through the tunable endless optical phase shifter to vary with an amount of a multiple of 2π radians without substantial change in lasing optical power.

In some embodiments, the tunable endless optical phase shifter can include a first optical switch, a second optical switch and first and second optical waveguide paths. Each optical waveguide path optically connecting a corresponding optical output of the first optical switch to a corresponding optical input of the second optical switch. At least one of the optical waveguide paths includes a tunable optical phase shifter thereon. In some such embodiments, the electronic control module can be capable of operating the optical switches to change one of the optical waveguide paths along which the light propagates therein without substantially changing the phase shift accumulated by the light through the tunable endless optical phase shifter other than a multiple of 2π.

In some embodiments, the wavelength-tunable optical filter can include at least one wavelength-tunable, optical loop-resonator.

In some embodiments, the optical gain module can include a semiconductor optical amplifier.

In some embodiments, one of the optical reflectors can include an optical reflecting loop, a Bragg reflector or a cleaved waveguide facet.

In some embodiments, the tunable endless optical phase shifter can further include the wavelength-tunable optical filter.

In some embodiments, the tunable endless optical phase shifter and the wavelength-tunable optical filter can be on a same photonic integrated circuit substrate. In some such embodiments, the optical gain module can be located on a semiconductor substrate which is positioned adjacent to the photonic integrated circuit substrate.

In some embodiments, the optical gain module can be optically serially coupled to the tunable endless optical phase shifter and the wavelength-tunable optical filter.

Any such embodiments can further include: a device configured to produce optical coherence tomograph images by varying an output wavelength of light from the external cavity laser, a Laser Imaging Detection and Ranging device comprising the external cavity laser and the electronic control module and being configured to sweep an output wavelength of the external cavity laser, or, an optical spectrometer device comprising the external cavity laser and the electronic control module and being configured to sweep an output wavelength of the external cavity laser.

Another embodiment includes another apparatus, the apparatus including an external cavity laser with an optical cavity, the optical cavity bounded by optical reflectors. The optical cavity includes an optical gain module capable of amplifying light, and a tunable endless optical phase shifter. The apparatus also includes an electronic control module connected to enable adjustment of a phase shift accumulated by the light propagating through the tunable endless optical phase shifter. Some such embodiments of the apparatus can include the any of the embodiments of the electronic control module, the tunable endless optical phase shifter and the devices as described here,

### BRIEF DESCRIPTION

The embodiments of the disclosure are best understood from the following detailed description, when read with the accompanying FIGUREs. Some features in the figures may be described as, for example, “top,” “bottom,” “vertical” or “lateral” for convenience in referring to those features. Such descriptions do not limit the orientation of such features with respect to the natural horizon or gravity. Various features may not be drawn to scale and may be arbitrarily increased or reduced in size for clarity of discussion. Reference is now made to the following descriptions taken in conjunction with the accompanying drawings, in which:

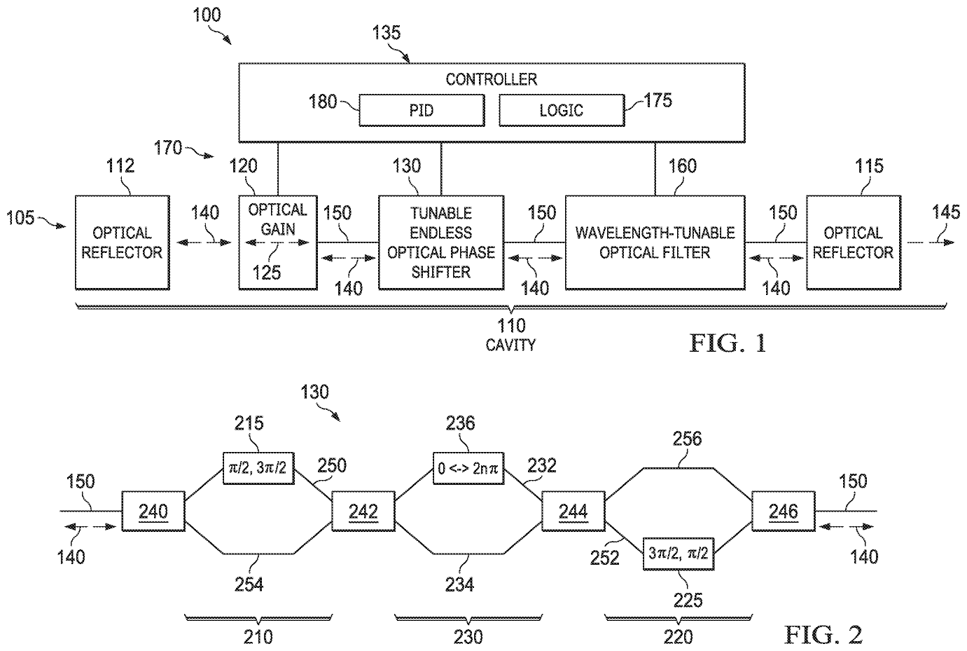

FIG. 1 presents a schematic block diagram showing aspects of an apparatus embodiment of the disclosure;

FIG. 2 presents a schematic view of an embodiment of a tunable endless optical phase shifter included in any of the apparatus embodiments discussed in the context of FIG. 1;

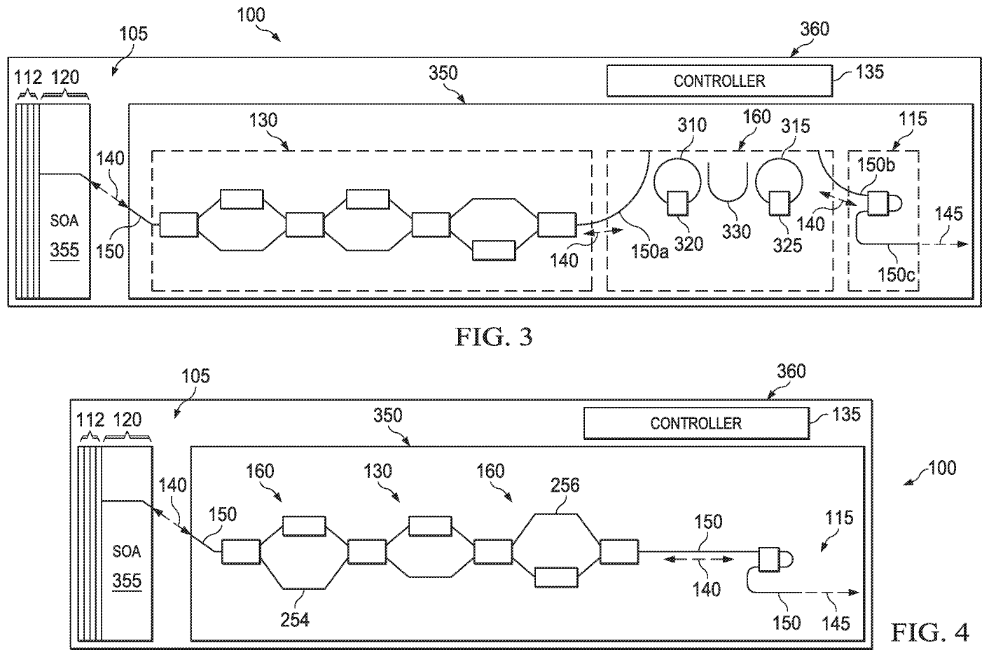

FIG. 3 presents a schematic view of an example apparatus of the disclosure such as described in the context of FIGS. 1 and 2 and further including a wavelength-tunable optical filter module;

FIG. 4 presents a schematic view of another example apparatus of the disclosure such as described in the context of FIGS. 1 and 2 and further including a delay-interferometric wavelength-tunable optical filter incorporated into a tunable endless optical phase shifter of the apparatus; and

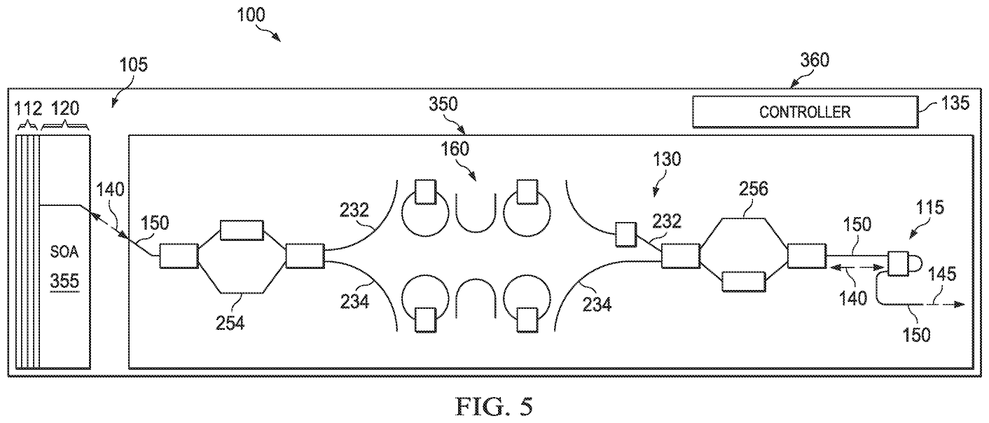

FIG. 5 presents a schematic view of another example apparatus of the disclosure such as described in the context of FIGS. 1 and 2 and further including a ring resonator wavelength-tunable optical filter incorporated into a tunable endless optical phase shifter of the apparatus.

In the Figures and text, similar or like reference symbols indicate elements with similar or the same functions and/or structures.

In the Figures, the relative dimensions of some features may be exaggerated to more clearly illustrate one or more of the structures or features therein.

Herein, various embodiments are described more fully by the Figures and the Detailed Description. Nevertheless, the inventions may be embodied in various forms and are not limited to the embodiments described in the Figures and Detailed Description of Illustrative Embodiments.

### DETAILED DESCRIPTION OF ILLUSTRATIVE EMBODIMENTS

The description and drawings merely illustrate the principles of the inventions. It will thus be appreciated that those skilled in the art will be able to devise various arrangements that, although not explicitly described or shown herein, embody the principles of the inventions and are included within their scope. Furthermore, all examples recited herein are principally intended expressly to be for pedagogical purposes to aid the reader in understanding the principles of the inventions and concepts contributed by the inventor(s) to furthering the art, and are to be construed as being without limitation to such specifically recited examples and conditions. Moreover, all statements herein reciting principles, aspects, and embodiments of the inventions, as well as specific examples thereof, are intended to encompass equivalents thereof. Additionally, the term, “or,” as used herein, refers to a non-exclusive or, unless otherwise indicated. Also, the various embodiments described herein are not necessarily mutually exclusive, as some embodiments can be combined with one or more other embodiments to form new embodiments.

Embodiments of the invention benefit from our recognition of the advantages of providing an external cavity semiconductor laser with a tunable endless optical phase shifter with a reset capability. Because the phase shifter can be continuously varied between two phase values of a range, e.g., between 0 to 2nπ phase shifts with “n” being an integer such as 1 (e.g., a multiple of 2π radians), and then, can be reset to the initial phase value, e.g., 0, without changing the optical path length through the phase shifter, i.e., during the reset operation. Also, the optical output power of the laser may stay about constant for a surprisingly broad wavelength range, e.g., involving multiple scans of the range and resets of the phase shift between the scans. Advantageously, the resetting of the phase shifter incorporated into an external cavity semiconductor laser does not introduce a discontinuity (mathematically discontinuous) in the output power, lasing wavelength and phase. During the reset process, although light propagates through two or more optical paths having substantially different optical path lengths, two or more longitudinal modes associated with the different paths inside the cavity add up coherently at the output generating a CW output. Advantageously, during the reset process, the resetting of the phase shifter incorporated into an external cavity semiconductor laser would not introduce random discontinuities in the output power, lasing wavelength and phase. That is resetting does not even cause a small change in the optical phase accumulated by laser light in the cavity, e.g., during the round trips of the laser cavity of the external cavity laser. A random discontinuous change in accumulated phase, during the reset operation, could cause a change in the lasing mode of the laser thereby substantially changing the output optical power of the laser, wavelength and phase.

Other advantages of the disclosed apparatus may include that the parts of the external cavity laser (e.g., the optical gain, tunable endless optical phase shifter, wavelength-tunable optical filter and other components thereof) can be fabricated on one or more semiconductor substrates and assembled to provide a solid state apparatus, e.g., a partially or totally integrated optical device such as a hybrid integrated optical device. We believe this, in turn, can improve the reliability and compactness of the variable-wavelength laser and may reduce the fabrication cost of some embodiments of such lasers, e.g., as compared to external cavity lasers that rely on mechanical moving parts to achieve wavelength scanning or wavelength tuning.

FIG. 1 presents a schematic block diagram of an apparatus 100, which is an embodiment of the disclosure.

The apparatus 100 includes an external cavity laser (e.g., laser 105, in some embodiments, an external cavity semiconductor laser) with an optical cavity (e.g., cavity 110). The optical cavity is bounded by optical reflectors (e.g., optical reflectors 112, 115). The optical cavity includes an optical gain module (e.g., optical gain 120) configured to amplify light of multiple wavelengths (e.g., multi-wavelength light 125), a tunable endless optical phase shifter (e.g., phase shifter 130). An electronic control module of the apparatus (e.g., controller 135) is electrically connected to operate the tunable endless optical phase shifter to vary the phase accumulated by various wavelengths of the light propagating therethrough. E.g. this variation of the accumulated phase of light propagating through the tunable endless optical phase shifter enables tuning of the cavity's lasing wavelength when the variation is performed in cooperation with a variation of the passband wavelength(s) of the wavelength-tunable optical filter. The wavelength of the output laser light from the external cavity semiconductor laser (e.g., lasing light 145) may be about continuously varied over a wavelength scanning range while the output light has at about a same optical power (e.g., ±5% or ±1% or less changes in power in some embodiments), e.g., due, at least in part, to an absence of changes of the laser cavity mode during such a lasing wavelength variation.

Herein, optical modules for various functions include one or more optical waveguides for performing the various functions. For example, the waveguides may be configured to include optical gain media for optical amplification. In some embodiments, such modules for amplification may include device(s) for optically or electrically pumping said optical gain media. For example, the waveguides may be configured to include one or more optical waveguide circuits for performing other functions such as optical filtering in a wavelength-dependent manner. Some examples of such optical modules include control electrodes, electrical heater(s) and/or cooler(s), and/or optical control interface(s). In some examples, such optical modules may be substantially planar integrated or hybrid-integrated modules. Some of the optical modules may include structures for performing multiple functions on light propagating therein.

As illustrated in FIG. 1, one or more of the optical modules or reflectors of the laser can be optically coupled to each other by optical waveguides (e.g., waveguides 145) and/or one more of the optical modules or reflectors can be coupled to each other through free-space.

The continuously varying a wavelength, means that there are no sudden jumps in the wavelength during the varying, e.g., such as might otherwise occur if the lasing mode of a laser cavity were to hop from one mode to another mode during the variation. The wavelength of the light amplified by the optical gain module (e.g., light 125) and output from the cavity of a laser (e.g., light 145) can be in a range of wavelengths in the visible and/or infrared wavelength regions (e.g., from 400 to 2000 nm in various embodiments). For example, in some embodiments, the light amplified by the optical gain module and the subsequent output emitted from the cavity of the laser can be centered at 1300 nm±50 nm or 1550 nm±50 nm (or ±25 nm or ±10 nm in some embodiments).

In some embodiments, the tunable endless optical phase shifter can about continuously or smoothly shift a phase accumulated by light propagating over an optical path therein (e.g., light 140) from an initial phase of 0 to 2nπ radians (where n is an integer of 1 or greater), and, then reset of the phase accumulated over the optical path to 0 radians without causing light passing through the tunable endless optical phase shifter to accumulate an intermediate phase in-between the initial phase and the 2nπ phase. That is, during the reset operation, light desirable accumulates the same phase by passing through the tunable endless optical phase shifter. For example, in some embodiments, to scan a wavelength of lasing light over the range of 50 nm (e.g., about 6.24 THz), in an optical cavity including a wavelength-tunable optical filter that can continuously tune over the wavelength range of 50 nm the tunable endless optical phase shifter can be controlled (e.g., by the electronic control module 135) to shift and to reset the optical cavity between two modes to cover the wavelength range of 50 nm which otherwise would require continuous phase shifts from phase values of 0 to 1000n radians.

FIG. 2 presents a schematic view of an embodiment of a tunable endless optical phase shifter 130 of apparatus 100 such as discussed in the context of FIG. 1. The tunable endless optical phase shifter can include any of the embodiments of such phase shifters disclosed in U.S. Pat. No. 8,787,708 to Doerr (“Doerr”), which is incorporated herein by reference in its entirety.

As illustrated, the tunable endless optical phase shifter includes a first optical switch (e.g., switch 210, a 1×2 or 2×2 optical switch), including an adjustable optical phase shifter (e.g., phase shifter 215), a second optical switch (e.g., switch 220, a 2×1 or 2×2 optical switch), also including an adjustable optical phase shifter (e.g., phase shifter 225) and an optical phase shifter structure (e.g., optical phase shifter structure 230) optically connecting the first switch to the second switch and has two parallel optical waveguides. Each of the optical waveguides (e.g., parallel waveguide arms 232 and 234) connect a corresponding optical output of the first optical switch to a corresponding optical input of the second optical switch. At least one of the waveguides (e.g., waveguide 232) includes a tunable optical phase shifter (e.g., phase shifter 236), although in some embodiments both waveguides 232, 234 can include a tunable phase shifter.

As illustrated, in some such embodiments, the tunable endless optical phase shifter includes a first Mach-Zehnder interferometer (MZI) switch (e.g., switch 210) including a phase shifter (e.g., phase shifter 215), a second MZI switch (e.g., switch 220) also including a phase shifter (e.g., phase shifter 225) and an optical phase shifter structure 230 (e.g., structure 230, a line phase shifter, such as referenced in Doerr) optically connecting the first MZI switch to the second MZI switch. The line phase shifter structure includes two waveguides (e.g., waveguide arms 232 and 234) at least one of the waveguides (e.g., waveguide 232) includes a phase shifter (e.g., phase shifter 236), although in some embodiments both waveguides 232, 234 can include a phase shifter. The phase shifter included in the first MZI switch (e.g., phases shifter 215) and the phase shifter included in the second MZI switch (e.g., phase shifter 225) are configured to substantially simultaneously switch from phase values of Φ₀ to Φ₀+π (e.g., from π/2 to 3π/2 in some embodiments) and from phase values of Φ₀+π to Φ₀ (e.g., from 3π/2 to π/2 in some embodiments), respectively, in response to a phase value of substantially 0 or 2nπ radians exhibited by the line phase shifter (e.g., phase shifter 236). The two waveguides in the line phase shifter structure (e.g., parallel waveguides 232 and 234) have an optical path length difference of 10 microns or less (or 5 microns or less, or 1 micron or less in some embodiments).

In some such embodiments, for which the optical switches are MZIs with tunable optical phase shifters, the electronic control module 135 (see FIG. 1) can operate the phase shifter included in the first MZI switch (e.g., phases shifter 215) and the phase shifter included in the second MZI switch (e.g., phase shifter 225) to cause light, received at either of the optical waveguides 150 to be transmitted to only one of the optical waveguides of the array connecting optical outputs of the 1×2 optical switch to optical inputs of the 2×1 optical switch. That is, received light, from the two waveguide arms of an optical MZI switch, destructively interferes at the input of one of the optical waveguides of the array and constructively interferes at the input of the other of the optical waveguides of the array. In addition, the electronic control module 135 would typically switch both of the optical switches together and would typically be configured to cause each of said optical phase shifters to produce two relative phase shift values on light traveling therethrough. For each optical phase shifter, the two values would typically differ by π radians so that light is switched between the upper and lower ones of the optical waveguides in response to the state of the optical switch being changed by the electronic control module 135. Such switching is typically provoked by the electronic control module 135 when the phase shifter on the one of the parallel optical waveguide paths is at the boundaries of its selected operating range.

Maintaining a substantially same optical path length of the two waveguide arms 232, 234 in the optical phase shifter structure 230 and simultaneously switching of the first and second switches 210, 220, (e.g., both switching at least within 30 degrees of each other and in some embodiments within 10 degrees or 5 degrees or 1 degrees of each other) during the optical phase shifter structure's resetting of the phase value to switch to the other one of the two parallel waveguides 232 and 234, can facilitate avoiding introducing, or reduce, discontinuities in the optical power of the lasing light output (e.g., FIG. 1, lasing light output 145) during the external cavity laser's operation.

Embodiments of the phase shifters may include thermo-optic phase shifters or charge injection-based electro-optic phase shifters, e.g., to facilitate rapid phase shifting and thereby minimize the time to reset the phase to its initial value (e.g., 0 degrees in some embodiments) and also increasing the scan rate.

During and after the reset of the tunable endless optical phase shifter 130 there can be a transition between one optical cavity mode and another optical cavity mode, e.g., due to coherent superposition at the output, but, the optical power and wavelength of the lasing light output (e.g., light 145) does not change. For instance, in some such embodiments, the lasing light output 145 can stay in a same optical power over the wavelength scanning range of the laser 105.

As illustrated, the optical phase shifter structure 230 and first and second MZI switches are optically interconnected by a 1×2 optical coupler 240, first and second 2×2 optical couplers, 242, 244 and a 2×1 optical coupler 246, although optical couplers having a greater number of (unused) optical ports could be used.

In some embodiments, one of waveguides arms of the first and second switches includes a tunable optical phase shifter (e.g., waveguide arms 250, 252 of MZI switches 210, 220, respectively) and another of the waveguide arms is a passive waveguide arm with no phase shifter (e.g., waveguide arms 254, 256 of MZI switches 210, 220, respectively), although in some embodiments both arms can include a tunable optical phase shifter.

In some embodiments of the apparatus, the optical cavity including the optical gain module and the tunable endless optical phase shifter can perform as a Fabry-Perot laser configured to emit an optical comb of discrete, substantially equally spaced frequency lines corresponding to the different cavity modes of the light 125 emitted by the apparatus.

Referring to FIG. 1, in some embodiments, the optical cavity 110 further includes a wavelength-tunable optical filter (e.g., wavelength-tunable optical filter 160), e.g., having one or more tunable wavelength bandpasses. The electronic control module 135 typically varies the bandpass wavelength(s) of the wavelength-tunable optical filter 160 simultaneously or in parallel with the variation of the phase shift produced by the tunable endless optical phase shifter 130. Then, the lasing wavelength of the laser may be adjusted without causing a change of lasing mode in the optical cavity 110. In some such embodiments, the tunable optical wavelength filter can filter the light with a filtering wavelength passband width in a range from 10⁻⁴ to 100 nm (or bandwidths of 1 to 100 nm or 10 to 100 nm in some embodiments).

In some such embodiments, such as when the optical gain module includes a semiconductor optical amplifier (SOA), the different wavelengths of the light (e.g., amplified spontaneous emission light emitted by a SOA) can be filtered by the wavelength-tunable optical filter in parallel with the continuously phase shifting of the light to produce multi-wavelength and phase shifted light (e.g., light 140). In some such embodiments, the different wavelengths of the light filtered by the wavelength-tunable optical filter can be changed over a wavelength scanning range.

FIG. 3 presents a schematic view of an example apparatus 100 of the disclosure such as described in the context of FIGS. 1 and 2 and further including an embodiment of the wavelength-tunable optical filter 160.

Some embodiments of the wavelength-tunable optical filter 160 can include at least one wavelength-tunable resonator (e.g., tunable ring or loop resonators 310 or 315). The resonator can be optically coupled to a waveguide (e.g., waveguide 150a) located to receive the light 140 (e.g., phase shifted and filtered light) from the tunable endless optical phase shifter and optically coupled to another waveguide (e.g., waveguide 150b) located to transmit the light 140 to one of the optical reflectors (e.g., reflective loop 115). The resonator can include a phase shifter (e.g., tunable phase shifter 320 or 325), e.g., to facilitate tuning the resonant wavelength thereof, e.g., over the wavelength scanning range of the apparatus (e.g., as controlled by the electronic control module 135). In some embodiments, the use of a wavelength-tunable optical filter having a single resonator (e.g., a single ring or loop) can provide a broad free spectral range (e.g., FSR of 50 nm, 100 nm or 150 nm) which could help reduce the number of output power discontinuities over the wavelength scanning range (e.g., a 50 nm, 25 nm, or 10 nm scanning range of the resonator or resonators).

Some embodiments of the wavelength-tunable optical filter 160 can include at least two resonators (e.g., tunable loop or ring resonator 310 and 315), e.g., such as part of a Vernier optical filter. For instance, the filter 160 can have two such resonators. The resonators can be optically coupled to a common waveguide (e.g., waveguide 330), one of the ring resonators can be optically coupled to a waveguide (e.g., ring resonator 310 coupled to waveguide 150a) located to receive the light from the tunable endless optical phase shifter. Another one of the ring resonators can be optically coupled to another waveguide (e.g., ring resonator 315 coupled to waveguide 150b) located to transmit the light 140 to one of the optical reflectors (e.g., optical reflector 115).

One skilled in the pertinent art would understand how the wavelength-tunable optical filter 160 could be configured as an all pass or an add drop loop or ring resonator. For instance, the two or more wavelength-tunable ring or loop optical resonators can be serially cascaded together and operated to have different free spectral ranges (FSPs). In the frequency domain, such a cascaded configuration of filters of different can increase the FSR of the laser via a Vernier effect. For example, the total optical roundtrip path length of each ring or loop optical resonator are different to produce the different FSRs, which enable a Vernier effect in a cascade of such optical filters. Wavelength filter tuning can be facilitated by tapping at a drop port such that one peak in optical intensity is passed through at one wavelength while intensities at other wavelengths are canceled out. One or more of such ring or loop optical resonator(s) can include a tunable phase shifter (e.g., phase shifters 320 and 325) to facilitate further tuning of passband wavelengths.

When one or more of the ring or loop optical resonators of the wavelength-tunable optical filter is wavelength-tuned, potentially a change of the lasing optical cavity mode, may be introduced. However, by tuning the filter module simultaneously or in parallel with the tunable endless optical phase shifter the number of such discontinuities can be dramatically reduced or even completely avoided. For instance, for an apparatus embodiment including a tunable endless optical phase shifter and a Vernier filter with two ring or loop optical resonators such as illustrated in FIG. 3, our simulations suggest that for a wavelength scanning range 50 nm (e.g., 6000 THz) there may be on average one discontinuity per 600 THz for such a method of operation. In contrast, with a conventional phase shifter (e.g., a phase shifter using mechanically driven gratings or mirror to change the optical phase) is used, there may on average one discontinuity, i.e., cavity mode hop, per 0.001 THz of wavelength scanning range or 1000 discontinuities per 1 THz of a wavelength scanning range or 600000 discontinuities per 600 THz of a wavelength scanning range depending on the cavity length.

With continuing reference to FIGS. 1 and 3, in some embodiments, the optical gain module 120 is or includes a semiconductor optical amplifier (SOA). For example, the SOA may be a reflective SOA (RSOA), which has a reflective layer corresponding to one of the optical reflectors (e.g., optical reflector 112). In some apparatus embodiments, one of the optical reflectors the external cavity semiconductor laser can be or include an optical reflecting loop mirror (e.g., a Sagnac loop mirror), a Bragg reflector or cleaved facet reflector (e.g., corresponding to optical reflector 115).

In some such embodiments, the reflective layer 112 of the RSOA can have a total or near-total reflective surface (e.g., 90% or greater or 99% or greater reflectivity in some embodiments), and, the optical reflector 115 can have a reflectivity that is less than the reflectivity of the reflective layer of the RSOA. In such embodiments, the lasing light output (e.g., lazing light output 145) from the external cavity semiconductor laser can be emitted from a waveguide of the reflective loop waveguide (e.g., waveguide 150c).

In some such embodiments, the reflective layer 112 of the RSOA can have a partial reflective surface (e.g., less than 90% or less than 99% in some embodiments), and, the optical reflector 115 can have a total or near-total reflectivity that is greater than the reflectivity of the reflective layer of the RSOA. In such embodiments, the lasing light output from the external cavity semiconductor laser can be emitted from the reflective layer of the RSOA.

FIG. 4 presents a schematic view of another example apparatus of the disclosure such as described in the context of FIGS. 1-2 in which a delay-interferometric wavelength-tunable optical filter is incorporated into a tunable endless optical phase shifter (e.g., components of a filter 160 incorporated into phase shifter 130). Such an embodiment may provide a compact apparatus design. For instance, the wavelength-tunable optical filter can be incorporated into arms of the optical switches of the tunable endless optical phase shifter 130 (e.g., arms 254 and 256 of optical switches 210 and 220, FIG. 2). For instance, in some embodiments, at least one loop or ring resonator of the wavelength-tunable optical filter can be incorporated into the arms of MZI switches of the tunable endless optical phase shifter 130.

In some embodiments, the first and second switches of the tunable endless optical phase shifter can include a single delay line arm (e.g., arms 254 and 256, respectively). The filter is tuned (e.g., scanned) using the phase shifter in the switch. The first and second switches have a same free spectral range (FSR). Each of the arms of a set have different path lengths than each other or different than the path length of the waveguide of the switch with the phase shifter (e.g., FIG. 2, arms 250, 252, respectively) to produce different delay times for light passage therethrough thereby producing a tunable wavelength filtering. In such embodiments, the phase shifters of the first and second switches (e.g., FIG. 2, phase shifters 215, 225, of first and second switches 210, 220 respectively) are adjusted to align the first passband peak in optical intensity of the first switch with the second passband peak optical intensity of the second switch. In the operation first and the second switches have substantially same free spectral range, e.g., same path length imbalance. For instance, in some embodiments, the first and the second switches can be adjusted to have an optical bandpass filter characteristic with substantially the same FSRs of less than about 100 nm.

FIG. 5 presents a schematic view of another example apparatus of the disclosure such as described in the context of FIGS. 1-2 in which a ring resonator wavelength-tunable optical filter is incorporated into a tunable endless optical phase shifter (e.g., components of a filter 160 incorporated into phase shifter 130). Such an embodiment may provide a compact apparatus design. For instance, analogous to that discussed in the context of FIG. 3, a single or a plurality of ring resonators of the wavelength-tunable optical filter 160 can be incorporated into arms of the inline phase shifter of the tunable endless optical phase shifter 130 (e.g., arms 232 and 234 of the inline phase shifter, FIG. 2). In such embodiments, when a reset of the phase shifter in the inline phase shifter is needed, the wavelength filters incorporated in the inline phase shifter are adjusted to align the first passband peak in the optical intensity of the first wavelength filter incorporated in the first arm of the inline phase shifter with the second passband peak optical intensity of the second wavelength filter incorporated in the second arm of the inline phase shifter. In this case, while light propagates through the second wavelength filter in the second optical path of the inline phase shifter, the wavelength filter in series with the phase shifter in the inline phase shifter can be reset substantially simultaneously with the phase shifter in the inline phase shifter.

As illustrated in FIG. 3, for some apparatus embodiments, the tunable endless optical phase shifter 130 and the wavelength-tunable optical filter 160 can be located on a same photonic integrated circuit substrate (e.g., substrate 350, a silicon, InP, or GaAs substrate, or a silica substrate). The optical gain module 120 can be located on the same photonic integrated circuit substrate, or, on a different semiconductor substrate (e.g., substrate 355, an InP or other group III-V or II-VI semiconductor substrate) which is positioned adjacent to the photonic integrated circuit substrate to optically communicate light (e.g., FIG. 1, lights 125, 140 respectively) with the tunable endless phase shifter and/or the wavelength-tunable optical filter.

As shown in FIG. 3, in some embodiment, the optical gain module 120 can be positioned adjacent to the tunable endless optical phase shifter 130. However, in other embodiments, the relative positions of the tunable endless phase shifter 130 and the wavelength-tunable optical filter 160 can be changed such that the optical gain module 120 is positioned adjacent to the wavelength-tunable optical filter 160.

One skilled in the pertinent art would be familiar with lithography deposition and patterning procedures to fabricate any of the optical components 112,115, 120, 130, 160, e.g., to manufacture an external cavity semiconductor laser 105 that is an integrated or hybrid integrated optical device with no mechanical moving parts. For example, various modules of the device may be fabricated with different semiconductor alloys and/or dielectrics such as silica, silicon-oxides and/or nitrides, and/or metal layers via techniques known micro-electronics and integrated optics fabrication.

As illustrated in FIGS. 3-5, for some embodiments of the apparatus 100 the optical gain module 120, tunable endless optical phase shifter 130, wavelength-tunable optical filter 160 and optical reflectors 112, 115 can be located on a same package substrate (e.g., an electro-optical printed circuit board package 360), and in some such embodiments, the electronic control module 135 can also located on the same package substrate 360, e.g., a monolithic semiconductor substrate.

Returning to FIG. 1, in some embodiments, the control module 135 can be or include a field-programmable gate array with interconnection circuits and a programmable logic block (e.g., interconnection circuit 170, logic block 175 including a computer processing unit, CPU, or microcontroller unit or analog circuitry) and can be configured to control an operational state of one of more or the optical gain module, the tunable endless optical phase shifter, and/or, the wavelength-tunable optical filter.

In some embodiments, the electronic control module can include an analog proportional integral derivative device (e.g., PID 180) configured to supply one or more control signals (e.g., electrical or optical signals as calculated by a CPU of the logic block 175 and sent by the interconnection circuits 170) to the optical gain module, the tunable endless optical phase shifter, and/or, the wavelength-tunable optical filter.

For instance, the control signals supplied by the electronic control module can for some embodiments: 1) cause the tunable endless optical phase shifter to change a phase shift value applied to the light (e.g., by causing an injection of charge into, or heating of, the phase shifters of the tunable endless optical phase shifter), 2) cause the optical gain module to emit and or amplify the light (e.g., by applying a drive current or optical pump power to the optical gain module, 3) maintain a temperature (±10, ±5, ±1 or ±0.1° C.) of the optical gain module and/or tunable endless phase shifter and/or wavelength-tunable optical filter, e.g., based on feedback of temperature measurements of these structures and transmitted to the electronic control module, 4) reset phase shift value of one of the optical waveguide paths of the parallel array in the tunable endless optical phase shifter, 5) displace the wavelength passband(s) of the wavelength-tunable optical filter, and/or 6) adjust of the passband wavelength(s) of the wavelength-tunable optical filter simultaneously or in parallel with the adjustment of the phase shift accumulated by light propagating through the tunable endless optical phase shifter. In some embodiments, the electronic control module can be configured to cause the wavelength scan range of the output laser light to be shifted to a neighboring range at a rate of at least about 1 kHz.

Any embodiments of the external cavity laser can a wavelength tunable light source in the apparatus where the apparatus is configured to be part of a device to produce optical coherence tomograph images, Laser Imaging Detection and Ranging (LIDAR), e.g., to produce distance measurements, or, a spectroscope.

Those skilled in the art to which this application relates will appreciate that other and further additions, deletions, substitutions and modifications may be made to the described embodiments.

What is claimed is:

1. An apparatus comprising:
an external cavity laser with an optical cavity, the optical cavity bounded by optical reflectors, wherein the optical cavity includes:
an optical gain module capable of amplifying light,
a tunable endless optical phase shifter, and
a wavelength-tunable optical filter; and
an electronic control module connected to enable adjustment of a phase shift accumulated by the light propagating through the tunable endless optical phase shifter and connected to enable adjustment of a passband wavelength of the wavelength tunable optical filter.

2. The apparatus of claim 1, wherein the electronic control module is capable of adjusting the accumulated phase shift and the passband wavelength in parallel.

3. The apparatus of claim 1, wherein the electronic control module is able to cause a phase shift accumulated by the light propagating through the tunable endless optical phase shifter to vary with an amount of a multiple of 2π radians without causing a substantial change in lasing optical power.

4. The apparatus of claim 1, wherein the tunable endless optical phase shifter includes:
a first optical switch;
a second optical switch; and
first and second optical waveguide paths, each optical waveguide path optically connecting a corresponding optical output of the first optical switch to a corresponding optical input of the second optical switch; and
wherein at least one of the optical waveguide paths includes a tunable optical phase shifter thereon.

5. The apparatus of claim 4, wherein the electronic control module is capable of operating the optical switches to change one of the optical waveguide paths along which the light propagates therein without substantially changing the phase shift accumulated by the light through the tunable endless optical phase shifter other than a multiple of 2π.

6. The apparatus of claim 2, wherein the electronic control module is capable of switching an optical path of the light propagating therethrough without changing the accumulated phase shift other than multiple of 2π.

7. The apparatus of claim 1, wherein the wavelength-tunable optical filter includes at least one wavelength-tunable, optical loop-resonator.

8. The apparatus of claim 2, wherein the wavelength-tunable optical filter includes at least one wavelength-tunable, loop resonator.

9. The apparatus of claim 8, wherein the electronic control module is capable of switching an optical path of light propagating therethrough without changing the accumulated phase shift other than a multiple of 2π.

10. The apparatus of claim 1, wherein the optical gain module includes a semiconductor optical amplifier.

11. The apparatus of claim 1, wherein one of the optical reflectors includes: an optical reflecting loop, a Bragg reflector or a cleaved waveguide facet.

12. The apparatus of claim 1, wherein the tunable endless optical phase shifter further includes the wavelength-tunable optical filter.

13. The apparatus of claim 1, wherein the tunable endless optical phase shifter and the wavelength-tunable optical filter are on a same photonic integrated circuit substrate.

14. The apparatus of claim 13, wherein the optical gain module is located on a semiconductor substrate which is positioned adjacent to the photonic integrated circuit substrate.

15. The apparatus of claim 1, wherein the optical gain module is optically serially coupled to the tunable endless optical phase shifter and the wavelength-tunable optical filter.

16. The apparatus of claim 2, wherein the electronic control module is configured to control an operational state of the optical gain module.

17. The apparatus of claim 2, further comprising a device configured to produce optical coherence tomograph images by varying an output wavelength of light from the external cavity laser.

18. The apparatus of claim 2, further comprising a Laser Imaging Detection and Ranging device comprising the external cavity laser and the electronic control module and being configured to sweep an output wavelength of the external cavity laser.

19. The apparatus of claim 2, further comprising an optical spectrometer device comprising the external cavity laser and the electronic control module and being configured to sweep an output wavelength of the external cavity laser.

20. An apparatus comprising:
an external cavity laser with an optical cavity, the optical cavity bounded by optical reflectors, wherein the optical cavity includes:
an optical gain module capable of amplifying light, and
a tunable endless optical phase shifter; and
an electronic control module connected to enable adjustment of a phase shift accumulated by the light propagating through the tunable endless optical phase shifter.
